(19) United States
(12) Patent Application Publication
(10) Pub. No.: US 2006/0006467 A1
(43) Pub. Date: Jan. 12, 2006

(54) Transistor structure and circuit suitable for input/output protection of liquid crystal display device

(76) Inventor: Yoshiaki Nakazaki, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/155,509

(22) Filed: Jun. 20, 2005

(30) Foreign Application Priority Data
Jul. 7, 2004 (JP) 2004-200418

(51) Int. Cl. H01L 27/01

(52) U.S. Cl. 257/347; 257/213

(57) ABSTRACT

A TFT structure and a circuit configuration, which are suitable, for example, for input/output protection of a liquid crystal display device, are provided. According to an embodiment of the invention, there is provided a TFT that includes a source region, a channel region and a drain region, which are formed in a Si thin film, and a gate insulation film and a gate electrode, which are formed over the channel region. A central portion and a source-side end portion of the channel region are formed of a substantially single-crystal semiconductor, and a drain-side end portion of the channel region is formed of a polycrystalline or amorphous semiconductor. The TFT is used in a protection circuit section, thereby enabling absorption of a surge voltage in the protection circuit section.

### CROSS-REFERENCE TO RELATED APPLICATIONS

This application is based upon and claims the benefit of priority from prior Japanese Patent Application No. 2004-200418, filed Jul. 7, 2004, the entire contents of which are incorporated herein by reference.

### BACKGROUND OF THE INVENTION

1. Field of the Invention

The present invention relates to a thin film transistor (TFT) that is suitably used, for example, in a protection circuit in an input/output circuit of an electronic device such as a liquid crystal panel device. In particular, the invention relates to the structure of a TFT having a protection function against static electricity that relates to current surge or voltage noise, and to an input/output protection circuit with a countermeasure to static electricity.

2. Description of the Related Art

In a conventional electronic device such as a liquid crystal display device, an electrostatic breakdown preventing circuit is normally provided between an input/output terminal and a first-stage transistor of an input/output circuit section of the electronic device. In other words, in usual cases, an electrostatic breakdown preventing circuit, which is formed using a semiconductor device with a low dielectric breakdown voltage such as a transistor or a diode, is provided in front of a first-stage transistor of an input/output circuit section.

FIG. 15 shows an equivalent circuit diagram of an input/output protection circuit 200 employing an n-channel TFT, which is used, for example, in a liquid crystal display device. FIG. 16 is an equivalent circuit diagram of an input/output protection circuit 220 employing a p-channel TFT. In FIG. 15, a voltage, which is to be applied to, e.g. an opposed electrode of each pixel of a liquid crystal display panel via an input/output terminal pad 201, is first applied to the input/output protection circuit 200. As is shown in FIG. 15, the input voltage is delivered to an input circuit (not shown) of the electronic device via resistors R11 and R15 that are connected in series. The input/output protection circuit 200 includes input/output protection TFTs 203 and 204, input resistor R11, and resistors R12 and R13 that are connected between the gates G and drains D of the input/output protection TFTs 203 and 204, respectively. A surge voltage is processed by the input/output protection TFTs 203 and 204 that are provided between the resistors R11 and R15. The input/output protection TFT 203 processes a positive surge voltage, and the input/output protection TFT 204 processes a negative surge voltage. A resistor R14 processes a surge that has not completely been processed by the input/output protection TFT 203. Behind these components, the input circuit of the electronic device is disposed via a resistor R15.

In this prior art, the input/output protection TFTs 203 and 204 are formed as TFTs with, e.g. SD (single drain) architectures, which have lower breakdown voltages than a TFT that is used in the input circuit (not shown). On the other hand, the TFT of the input circuit (not shown) is formed as a TFT with a so-called LDD (lightly doped drain) structure having a high breakdown voltage. In the description in this specification, the SD structure refers to an ordinary FET structure in which a drain region with a high impurity concentration directly adjoins a channel region with a low impurity concentration.

The input/output protection TFT 203 has a source S that is formed of a high-impurity-concentration diffusion layer and is connected to a power supply Vss. In addition, the input/output protection TFT 203 has a drain D that is connected via the resistor R12 to the gate G thereof. The input/output protection TFT 204 has a drain D that is formed of a high-impurity-concentration diffusion layer and is connected to a power supply Vdd. In addition, the drain D of the input/output protection TFT 204 is connected via the resistor R13 to the gate G thereof. Each of the input/output protection TFTs 203 and 204 can be made to function as a buffer that applies a voltage to, e.g. the opposed electrode (not shown) of the liquid crystal panel. The drain of the input/output protection TFT 203 and the source S of the input/output protection TFT 204 are connected to the input circuit of the prescribed electronic device via the resistor R15. FIG. 16 shows, as mentioned above, the input/output protection circuit 220 that is formed using p-channel transistors. The input/output protection circuit 220 has the same function as the input/output protection circuit 200 shown in FIG. 15 that is formed using the n-channel transistors.

Next, a snapback phenomenon of a MOSFET is explained with reference to FIG. 17 and FIG. 18. In an n-channel MOSFET with a structure shown in FIG. 17, a polysilicon layer 217 is formed on an insulating oxide film 211. A gate insulation film 212 is provided over the polysilicon layer 217. A gate electrode 213 is formed on the gate insulation film 212. Using the gate electrode 213 as a mask pattern, impurities are doped in the polysilicon layer 217 so that a drain region 214 and a source region 215 are formed in a self-alignment manner. That part of the polysilicon layer 217, which is masked under the gate electrode 213, that is, an intermediate region between the drain region 214 and source region 215, becomes a channel region 216.

In the n-channel TFT with this structure, the source region 215 is connected to a power supply Vss. The drain region 214 and gate electrode 213 are commonly connected and supplied with a control voltage Vcnt. The control voltage Vcnt is varied so as to control an application voltage Vds between the drain region 214 and source region 215. In this state, a variation in current Ids, which flows through the drain region 214 and source region 215, is examined. The result of the examination demonstrates that the relationship between the application voltage Vds and current Ids varies as indicated by a solid line in FIG. 18.

If the application voltage Vds is once increased to a breakdown voltage (breakout voltage) BVds or more, the current Ids suddenly begins to flow. Even if the application voltage Vds is decreased to the breakout voltage BVds or less, the current Ids does not decrease. Then, a secondary breakout occurs such that the current Ids increases with a lower application voltage Vds. This phenomenon is called “snapback phenomenon”.

In the voltage-current characteristics, the voltage at point P in FIG. 18 is called “hold voltage”, and the current at point P is called “hold current”. This snapback characteristic is generally referred to as “bipolar action of MOSFET”. In FIG. 18, if the difference in impurity concentration between the drain region and channel region in the TFT increases, the voltage-current characteristics vary from those indicated by the solid line to those indicated by a broken line. In the case of the p-channel TFT, too, the characteristics vary like the n-channel TFT, as shown in FIG. 19.

It is preferable to use the TFT of the LDD structure with the increased breakout voltage BVds and hold voltage, for instance, as the driving TFT for the liquid crystal panel. However, it is not proper to use the TFT of the LDD structure as an input/output protection TFT since it has a higher breakdown voltage. Thus, in the prior art, two kinds of TFTs are used in such a way that the TFT of the SD structure is used as the input/output protection TFT and the TFT of the LDD structure is used as the driving TFT for the liquid crystal display panel.

Since the LDD-structure TFT and SD-structure TFT are formed on the same substrate, this structure requires an additional mask for forming the LDD region. Moreover, such a problem arises that the number of fabrication steps and the cost increase for the formation of the LDD region.

In addition, a plurality of TFTs, which are used, for example, in a driving circuit for pixels and a protection circuit in the liquid crystal display device, are formed on the insulating substrate such that the TFTs are isolated from each other. Consequently, the substrate potential cannot be fixed, and a sufficient escape path for the current that enters the input/output protection circuit cannot be secured. Thus, the flow of the surge current causes electrostatic breakdown at the insulating film or connection part of the input/output protection TFT that constitutes the input/output protection circuit. Such a problem thus arises that the function of the input/output protection circuit, which should normally be implemented, cannot be executed.

In the structures shown in FIGS. 15 and 16, a sufficient escape path for the current that enters the input/output protection circuit cannot be secured. Consequently, electrostatic breakdown occurs at the insulating film or connection part of the input/output protection TFT that constitutes the input/output protection circuit, and such a problem thus arises that the normal function of the input/output protection circuit cannot be implemented.

### BRIEF SUMMARY OF THE INVENTION

In order to solve the above-described problem, the present invention adopts TFTs with special structures according to embodiments that are described below. In addition, the invention provides a protection circuit that uses the TFTs with the special structures.

According to an embodiment of the present invention, there is provided a TFT (first TFT) comprising: a source region, a channel region and a drain region, which are formed in a semiconductor thin film, and a gate insulation film and a gate electrode, which are formed over the channel region, wherein a central portion and a source-side end portion of the channel region are provided in a substantially single-crystal semiconductor, and a drain-side end portion of the channel region is provided in a polycrystalline or amorphous semiconductor.

According to another embodiment of the present invention, there is provided a TFT (second TFT) comprising: a source region, a channel region and a drain region, which are formed in a semiconductor thin film, and a gate insulation film and a gate electrode, which are formed over the channel region, wherein a central portion and a drain-side end portion of the channel region are provided in a substantially single-crystal semiconductor, and a source-side end portion of the channel region is provided in a polycrystalline or amorphous semiconductor.

According to still another embodiment of the present invention, there is provided a TFT comprising: a source region, a channel region and a drain region, which are formed in a semiconductor thin film, and a gate insulation film and a gate electrode, which are formed over the channel region, wherein the semiconductor thin film is formed of a recrystallized semiconductor thin film, and the channel region is formed of a growth start region and a crystal-growth region of the recrystallized semiconductor thin film.

According to still another embodiment of the present invention, there is provided an input/output protection circuit for an electronic device, the circuit comprising at least a plurality of TFTs, wherein the input/output protection circuit includes an input/output terminal section that receives an input signal, an input/output circuit section that delivers the input signal to the electronic device, and a protection circuit section that is provided between the input/output terminal section and the input/output circuit section, the protection circuit section is formed using at least the first TFT, and the input/output circuit section is formed using at least the second TFT.

According to the invention, the input/output protection circuit is formed using the TFT that includes the polycrystalline silicon or amorphous silicon region with many crystal defects at the drain-side end portion of the channel region. On the other hand, the input/output circuit is formed using the TFT that has the entire channel region formed in the recrystallized substantially single-crystal semiconductor region with good crystallinity and a large grain size. With this structure, the protection circuit can be formed without increasing the number of masks and fabrication steps in order to form two types of TFTs with different breakdown voltages BVsd.

By virtue of the formation of the polycrystalline silicon or amorphous silicon region with many crystal defects at the drain-side end portion of the channel region, even if an undesirable electrostatic surge current is input, the surge current can be alleviated by the crystal defects in the polycrystalline silicon or amorphous silicon. Therefore, destruction of the input/output protection TFT can be prevented.

Furthermore, TFTs are fabricated using a silicon recrystallizing technique such as a phase modulation excimer laser Ameling method (PM-EcA) that is to be described below. Thereby, a polycrystalline silicon or amorphous silicon region and a substantially single-crystal recrystallized region with a large grain size can easily be formed. Thus, two types of TFTs with two different breakdown voltages BVsd can easily be formed on the same substrate.

### BRIEF DESCRIPTION OF THE SEVERAL VIEWS OF THE DRAWING

FIG. 1A to FIG. 1C are views that illustrate a recrystallization step using a phase shift mask according to an embodiment of the present invention;

FIG. 2A and FIG. 2B show an example of the phase shift mask according to the embodiment of the invention;

FIG. 3 is a microscopic photograph of a concrete example of a recrystallized semiconductor thin film that is used in the present invention;

FIG. 4 shows a crystallizing apparatus that is usable in recrystallizing a semiconductor thin film according to the present invention;

FIG. 5 is a plan view that shows the structure of an input/output protection transistor according to a first embodiment of the invention;

FIG. 6 is a cross-sectional view of the structure of the input/output protection transistor according to the first embodiment of the invention;

FIG. 7 is a plan view that shows the structure of an input/output transistor according to a second embodiment of the invention;

FIG. 8 is a cross-sectional view of the structure of the input/output transistor according to the second embodiment of the invention;

FIG. 9A and FIG. 9B show the structure of a thin-film transistor according to a third embodiment of the invention;

FIG. 10A and FIG. 10B are graphs that show simulation results of an internal electric field and a potential in the structures of the thin-film transistors according to the first and second embodiments of the invention;

FIG. 11 is a graph that shows a simulation result of a source-drain breakdown voltage in the structure of the thin-film transistor according to the first and second embodiments of the present invention;

FIG. 12 is a graph that shows an actual measurement result of the source-drain breakdown voltage in the structure of the thin-film transistor according to the first and second embodiments of the present invention;

FIG. 13 shows an input/output protection circuit according to a fourth embodiment of the invention, which uses the n-channel thin-film transistors relating to the present invention;

FIG. 14 shows an input/output protection circuit, which uses the p-channel thin-film transistors relating to the present invention;

FIG. 15 shows a prior-art input/output protection circuit that uses n-channel transistors;

FIG. 16 shows a prior-art input/output protection circuit that uses p-channel transistors;

FIG. 17 illustrates a method of measuring snapback characteristics of the MOSFET;

FIG. 18 shows snapback characteristics of an n-channel MOSFET;

FIG. 19 shows snapback characteristics of a p-channel MOSFET; and

FIGS. 20A and 20B show a concrete example of a liquid crystal display device that employs an input/output protection circuit that is formed according to the present invention.

### DETAILED DESCRIPTION OF THE INVENTION

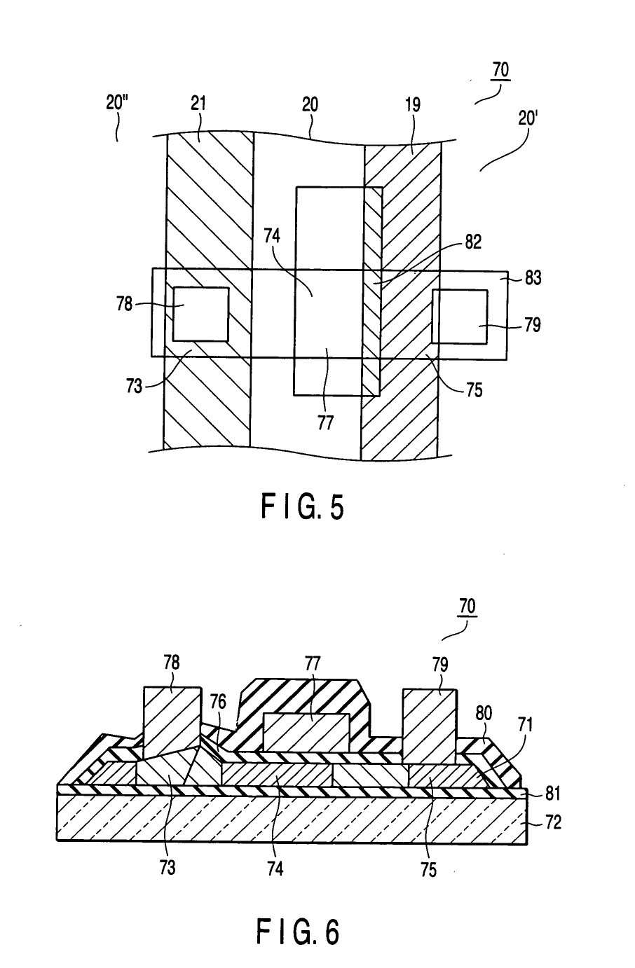

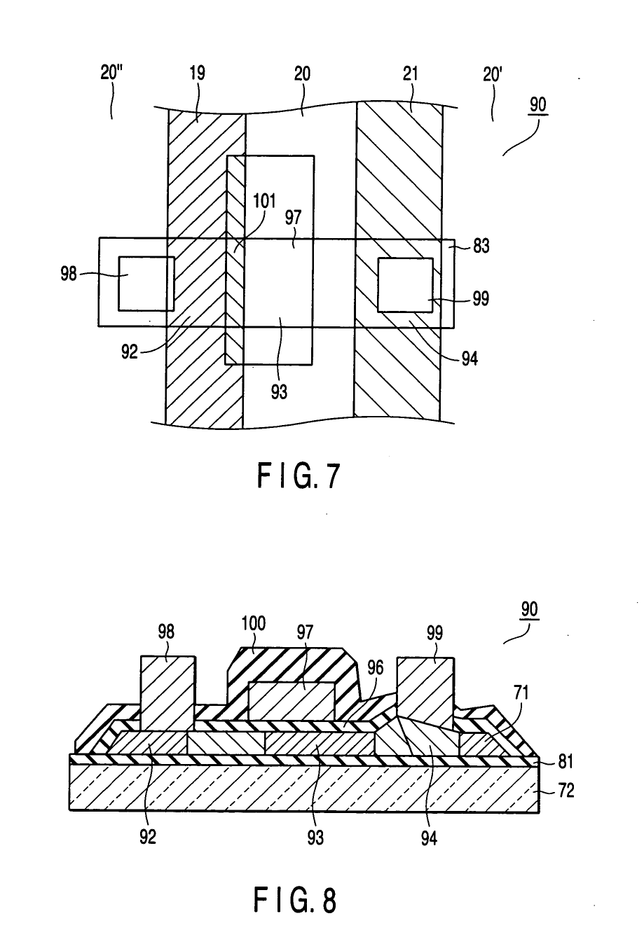

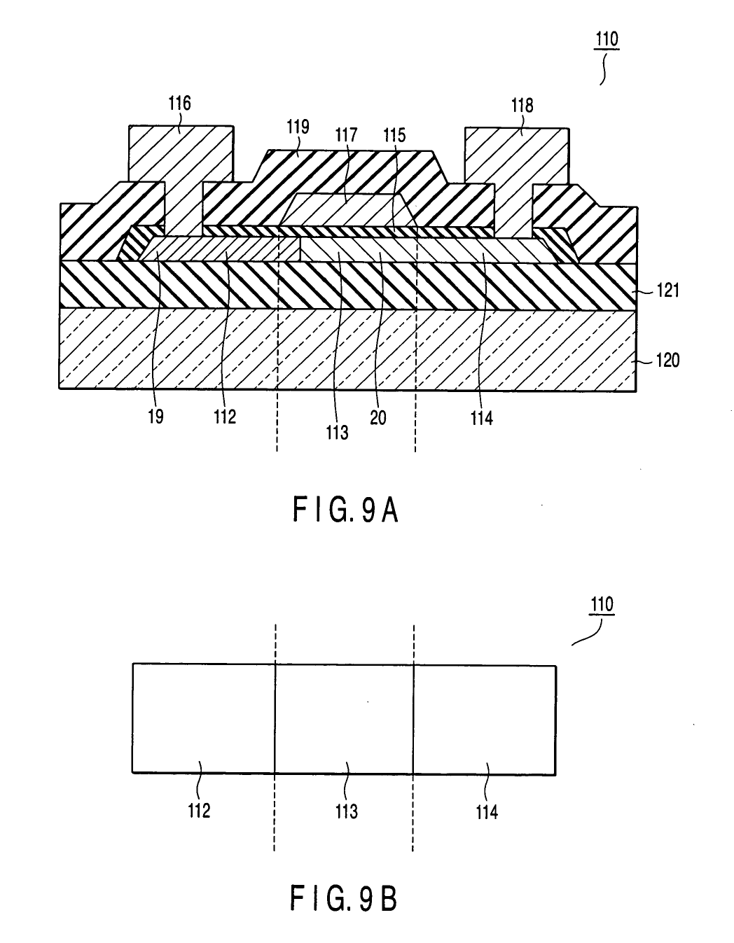

Embodiments of the present invention will now be described in detail with reference to the accompanying drawings. Transistors 70 (see FIGS. 5 and 6), 90 (see FIGS. 7 and 8) and 110 (FIG. 9) for input/output protection according to embodiments of the present invention are not formed using an amorphous Si thin film that is usually used in fabricating TFTs, such as an amorphous Si thin film that is uniformly formed on a glass substrate. Instead, these transistors are formed using semiconductor thin films that are formed through special recrystallization steps, as are exemplified below.

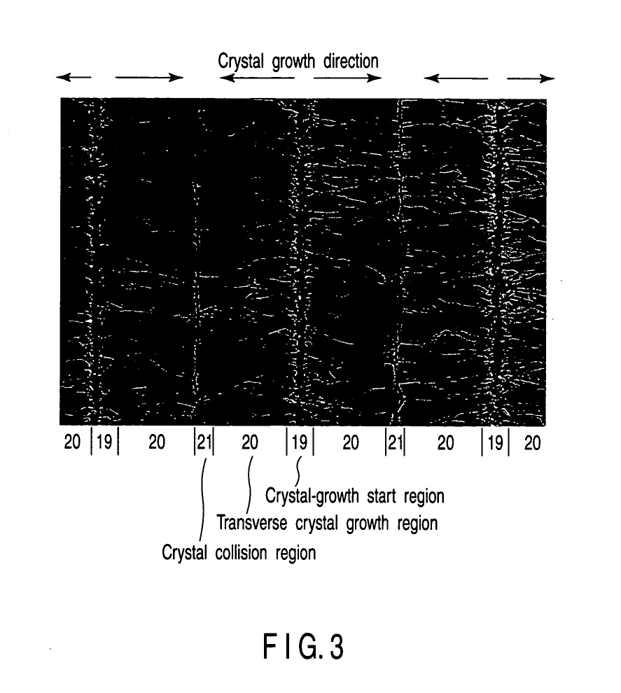

In the present invention, a TFT is formed using a semiconductor thin film (e.g. Si thin film or Ge thin film) 71 that includes, as shown in FIG. 5, at least a substantially single-crystal, large-grain-size recrystallized region (i.e. transverse crystal-growth region) 20 and a polycrystalline or amorphous region (i.e. crystal-growth start region) 19. The channel region of the TFT is formed in the substantially single-crystal region 20, and the polycrystalline or amorphous region, that is, the crystal-growth start region 19. As the semiconductor thin film that includes at least the substantially single-crystal region and the polycrystalline region, it is possible to use a Si thin film that includes, as shown in a photo of FIG. 3, at least mutually adjacent, substantially striped crystal-growth start region 19 and transverse crystal-growth region 20, and a crystal collision region 21. The Si thin film can uniformly be formed on a large insulting substrate that is used, e.g. in a liquid crystal panel.

The crystal-growth start region 19, as shown in the photo of FIG. 3, is formed as a polycrystalline region comprising many fine crystals each with a grain size of about 0.2 μm. At the crystal grain boundaries, there are electrically active defects that function as centers of generation/recombination of carriers. In general, it is undesirable to use such a region, which comprises many polycrystals, as an active region of the TFT, except for a part that is doped with impurities at a high concentration. However, in the present embodiment, this polycrystalline region is positively used as a part of the channel region of the TFT. A description will now be given of an example of the method of forming the Si thin film that includes the transverse crystal-growth region 20, crystal-growth start region 19 and crystal collision region 21.

The TFT according to the present invention is formed in a silicon thin film that is recrystallized by a phase modulation excimer layer crystallization method, which is described below. In the case where a substrate on which a silicon thin film is to be formed is a glass substrate, high temperatures as in a case of fabricating a silicon wafer cannot be used in order to obtain a single crystal. To begin with, an amorphous or polycrystalline silicon thin film, for instance, is formed on a glass substrate by an arbitrary method. Then, a pulse-like excimer laser beam is applied to the amorphous or polycrystalline silicon thin film, thereby melting the silicon thin film. The molten silicon thin film is recrystallized and a silicon thin film, which is partly made into a single crystal, is obtained. In this embodiment, silicon is used, but the usable semiconductor material is not limited to silicon. For instance, germanium or a Group III-V semiconductor may be used.

When recrystallization is performed, it is necessary to obtain a recrystallized region comprising a single crystal portion with a largest possible area and a great grain size. One possible method for achieving this is as follows. The thin film is melted such that a temperature distribution in a transverse direction is given to each of striped regions. With the temperature distribution or gradient being maintained, the temperature of the substrate is lowered and thus the silicon thin film is recrystallized. In order to obtain such a temperature distribution, it is possible to adopt such a method that the intensity of an excimer laser beam, which is applied to the substrate surface, is provided with a spatial distribution by using a phase shift mask with a proper pattern, thereby providing a transverse temperature gradient to each striped region.

According to this method, after the irradiation of the laser beam, the temperatures of the respective parts of the substrate decrease on the basis of the temperature gradient at the time of melting, and crystal growth in the transverse direction occurs successively from the lowest-temperature part toward the high-temperature part. Thus, from the initially produced polycrystalline portion, crystal growth progresses with a seed of crystal portion that is particularly suited to crystal growth, and a plurality of large single-crystal regions, which are equal in size to the channel regions of the individual TFTs, that is, a plurality of recrystallized regions with large grain sizes, are formed. With this method, it is possible to obtain stripe-shaped regions each comprising a plurality of transversely grown single crystals with a grain size of, e.g. several μm to 10 μm.

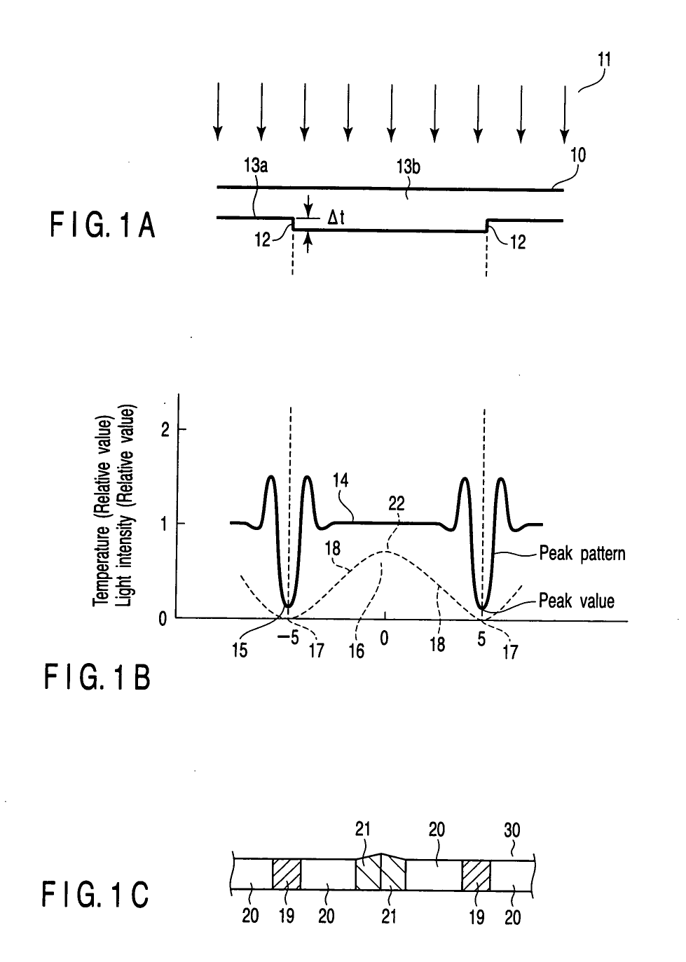

Referring now to FIG. 1, the recrystallizing step using a phase shift mask 10 is described. In FIG. 1, an incident excimer laser beam 11 is homogenized by a publicly known homogenizing optical system that homogenizes the light intensity. The phase shift mask 10, as shown in FIG. 1A, is formed such that a transparent medium, such as a quartz material, is provided with mutually adjacent regions with different thicknesses. At stepped portions 12 (phase shift portions) between these adjacent regions, the incident excimer laser beam 11 is diffracted or interfered. In this manner, a cyclic spatial distribution is imparted to the intensity of the incident laser beam.

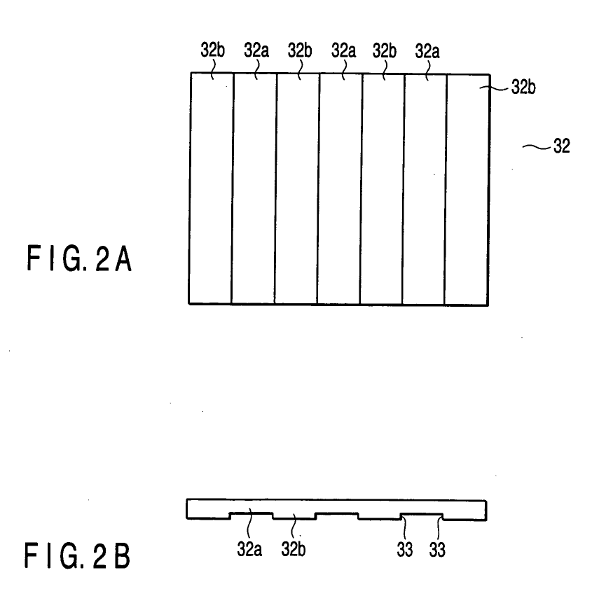

The phase shift mask 10 is configured such that laser beams that have emerged from the mutually adjacent patterns have opposite phases (with a 180° phase difference). Specifically, alternately arranged stripe regions, as shown in FIG. 2, comprise a first strip region (phase region) 13a with a phase π of transmissive light and a second strip region (phase region) 13b with a phase 0 of transmissive light. Each strip region has a width of 10 μm in this example.

To be more specific, in the case of using a KrF excimer laser with a wavelength of, e.g. 248 nm, the phase shift mask 10 is fabricated by pattern-etching a rectangular quarts plate with a refractive index of 1.5 so as to have a depth corresponding to a phase π relative to light with a wavelength of 248 nm, that is, a depth of 248 nm. The region that is thinned by etching becomes the first strip region 13a, and the non-etched region becomes the second strip region 13b. A step Δt between the strip regions 13a and 13b corresponds to a phase difference θ of the respective laser beams. The phase difference θ is given by θ=2πΔt(n−1)/λ, where λ is the wavelength of the laser beam and n is the refractive index of the quartz substrate.

When the phase shift mask 10 with this structure is used, the excimer laser beam 11 that has passed through the thick second phase region 13b delays by 180°, relative to the excimer laser beam that has passed through the thin first phase region 13a. As a result, interference and diffraction occur between the laser beams. A laser beam intensity distribution 14, as shown in FIG. 1B, is obtained. Specifically, since the laser beams that have passed through the adjacent phase regions have opposite phases, a laser beam that has passed through the phase shift portion between the adjacent phase regions has a minimum light intensity, for example, 0. The temperature of a portion 15 with the minimum light intensity decreases to the minimum, and a temperature distribution 16, as shown in FIG. 1B, is provided on the substrate surface.

When the irradiation of the laser beam is stopped, a lowest-temperature region 17 or a region near the region 17 has a temperature of a melting point or lower, and a great number of polycrystals that are nuclei for semiconductor recrystallization occur in the region. At first, polycrystals are produced in the lowest-temperature region 17, and the aforementioned so-called crystal-growth start regions 19 are formed. However, while crystals are transversely grown in succession in accordance with the temperature gradient of a temperature gradient portion 18, a crystal portion with a crystal orientation, which is particularly suitable for crystal growth, grows from the lowest-temperature part in the transversely direction. Thus, at each temperature gradient portion 18, a recrystallized region that comprises a substantially large single-crystal region with a large grain size, that is, a region (transverse crystal-growth region) 20 where a crystal is transversely grown from the crystal-growth start region 19, as shown in FIG. 3, is obtained. In the vicinity of a highest-temperature portion 22, single crystals that have grown from both sides collide with each other, and a polycrystalline portion, that is, the crystal collision region 21, is formed.

FIG. 1C is a cross-sectional view that shows the polycrystalline crystal-growth start region 19, the recrystallized region 20 that comprises the substantially large single crystal region with the large grain size where the transverse crystal growth is made from the crystal-growth start region 19, and the collision region 21 where crystals grown from both sides collide with each other, which are all formed in the semiconductor thin film 30, as described above.

If the phase shift mask is formed in successive stripes (32a, 32b), for example, as shown in FIG. 2, it is possible to form on the insulating substrate a plurality of crystal-growth start regions 19, recrystallized regions 20 with large grain sizes and crystal collision regions 21, which are successive in stripes. FIG. 2A is a plan view of this type of phase shift mask, and FIG. 2B is a cross-sectional view of the phase shift mask. In the case where the phase shift mask 32 shown in FIG. 2 is used, a lowest-temperature portion is formed in a linear shape along a stepped portion 33. The shape of the phase shift mask is not limited to this. If a properly formed phase shift mask pattern is used, the minimum-light-intensity portion 15, that is, the lowest-temperature portion 17, can be formed, for example, in a lattice shape or a dot shape.

In the above-described embodiment of the invention, it is necessary that the channel region of the TFT be formed in the region that includes the substantially single crystal region and the region with many crystal defects, for example, the polycrystalline semiconductor region or amorphous semiconductor region. The method of forming the substantially single crystal region and the region including crystal defects is not limited to the above method. Another possible method is as follows. An amorphous semiconductor thin film is formed over the entirety of an insulating substrate, and a laser beam is applied to predetermined parts that are to be made into single crystals, thereby melting and recrystallizing the predetermined parts. Thus, a substantially single crystal region and an amorphous region are formed. The expression “substantially single crystal region” is used for the following reason. For example, the transverse recrystallized region 20 is not formed as a complete single crystal, but it is formed as single crystal portions with such a size as to permit formation of the operational region of each TFT in each single crystal portion of the transverse recrystallized region 20. It is also possible that the operational region of each TFT is formed of a plurality of single crystal portions.

FIG. 3 shows a microscopic photograph of a recrystallized semiconductor thin film. It is understood that substantially fan-shaped crystals grow in the transverse direction from the polycrystalline crystal-growth start regions 19. It is also understood that crystal growth progresses in the transverse direction and the fan-shaped recrystallized region 20, which can be regarded as a substantially single crystal and has a large size, compared to the dimension of the TFT with a gate width of about 1 μm, is formed.

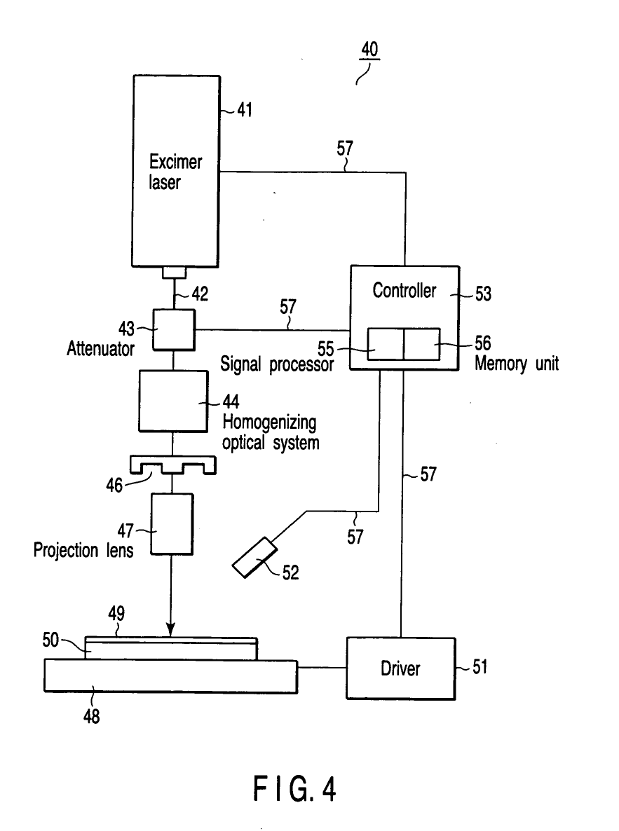

FIG. 4 shows an embodiment of a crystallizing apparatus 40 that is usable in the recrystallization of the semiconductor thin film according to the present invention. In this example, an excimer laser 41 (e.g. XeCl, KrF, etc.) is used as a laser light source. The laser light source, however, is not limited to such an excimer laser. As is shown in FIG. 4, on the emission side of the excimer laser 41 that emits a pulse laser beam 42, there are successively provided an attenuator 43 for controlling the energy density of the laser beam 42 and a homogenizing optical system 44 for homogenizing the intensity of the laser beam. The attenuator 43 and homogenizing optical system 44 are ordinary ones that are used in conventional optical apparatuses. A phase shift mask 46 is disposed on the emission side of the homogenizing optical system 44. A laser beam pattern, which is formed by the phase shift mask 46, is passed through a projection lens 47 with an unchanged size or with a reduced size.

An XY stage 48 that is movable in a direction perpendicular to the direction of travel of the laser beam is disposed on the emission side of the projection lens 47. An insulating substrate 50, on which a semiconductor thin film 49 is formed, is to be placed on the XY stage 48. The XY stage 48 is connected to a driver 51 and is moved by the driver 51 in a direction perpendicular to the direction of the laser beam. A light receiving device 52 for detecting the position of the semiconductor thin film 49 is provided above the XY stage 48.

The excimer laser 41, attenuator 43, driver 51 and light receiving device 52 are electrically connected to a controller 53 over signal lines 57. The controller 53 includes a signal processor 55 that processes signals from these components 41, 43, 51 and 52 and generates necessary control signals for the components, and a memory unit 56 that stores information and programs, which are necessary for signal processing. The controller 53 includes a program that enables formation of recrystallized regions with large grain sizes in the amorphous or polycrystalline semiconductor thin film 49 by means of excimer laser irradiation. The controller 53 can execute various controls that are necessary for the recrystallizing apparatus, including a light emission control of the excimer laser 41 that emits a pulse laser beam, an energy density control of the attenuator 43, a driving control of the XY stage 48 by means of the driver 51, and a position detection control for the semiconductor thin film 49 by means of the light receiving device 52.

FIG. 5 shows a TFT 70 according to a first embodiment of the present invention. FIG. 5 shows a positional relationship between the structure of the TFT, which is formed in a semiconductor thin film and is usable, for example, as an input/output protection circuit of a liquid crystal display device, and the structure of a recrystallized semiconductor thin film.

The TFT 70 is formed in an Si thin film 71 that is recrystallized by the above-described phase modulation excimer layer crystallizing method. The Si thin film 71 is formed on an insulating substrate 72 such as a glass substrate, a quartz substrate or a plastic substrate, as shown in FIG. 6. An Si thin film with a thickness of, e.g. about 30 nm to 200 nm, preferably about 50 nm to 100 nm, is formed on the insulating substrate 72 by a conventional film forming method such as CVD, evaporation or sputtering. The formed Si thin film is recrystallized by the phase modulation excimer laser Ameling method. The TFT 70 can be formed as a p-channel TFT or an n-channel TFT by properly selecting the kind and concentration of impurities, which are to be doped in the respective regions by, e.g. ion implantation, in accordance with the need in connection with the circuit configuration.

The Si thin film 71, which is recrystallized by the phase modulation excimer laser Ameling method, includes a crystal-growth start region 19, which includes fine crystal Si with a grain size of about 0.2 μm or less, a transverse crystal-growth region 20, in which crystals are transversely grown, and a collision region 21, in which the transversely grown-crystals collide with each other. A plurality of TFTs that constitute the input/output protection circuit are formed in these regions, as desired. FIG. 6 is a cross-sectional view of the TFT 70 that is formed in an island shape by etching away a peripheral part of the TFT for device isolation.

As shown in FIG. 5 by way of example, the Si thin film 71 of the TFT 70, which is formed as an input/output protection transistor, includes a source region 73, a channel region 74 and a drain region 75. In this example, the Si thin film 71 is formed as a rectangular Si island 83 such that the peripheral part of each TFT 70 is etched away for isolation of the TFTs 70. Over the Si thin film 71, there are provided a gate insulation film 76 of, e.g. SiO₂ with a thickness of 30 to 200 nm, a gate electrode 77, a source electrode 78, a drain electrode 79 and an interlayer insulation film 80.

Each of the electrodes may be formed by selectively using polysilicon, tungsten-molybdenum alloy, aluminum, or other high-melting-point metal material, which has a thickness of, e.g. 200 to 300 nm, depending on electrical characteristics and work function that the respective electrodes require. In the case where aluminum films are used as the source electrode 78 and drain electrode 79, it is better to provide a titanium thin film as barrier metal between the aluminum film and the Si thin film. An undercoat insulation film 81 of, e.g. SiO₂ may be provided on the insulating substrate 72, where necessary.

In the TFT structure shown in FIG. 5, the crystal-growth start region 19, which includes many fine crystals and has many crystal defects, is configured to overlap the drain region 75 and channel region 74. Thus, a drain-side end portion 82 of the channel region 74 is formed in the crystal-growth start region 19. In other words, a source-side end portion and most of a central portion of the channel region 74 are formed in the transverse crystal-growth region 20 that are substantially formed of single crystals. The drainside end portion 82, for example, a right-side part of about 20% of the channel region 74 in FIG. 5, is formed in the crystal-growth start region 19.

In FIG. 5, the drain region 75 is formed in the crystal-growth start region 19 and a right-side transverse crystal-growth region 20′ in FIG. 5. Depending on cases, the drain region 75 may be formed only in the crystal-growth start region 19. The reason for this is that the drain region 75 is doped with impurities at a high concentration of about 20²⁰/cm³, and so the crystal-growth start region 19 and transverse crystal-growth region 20 function as electrically equivalent resistor portions.

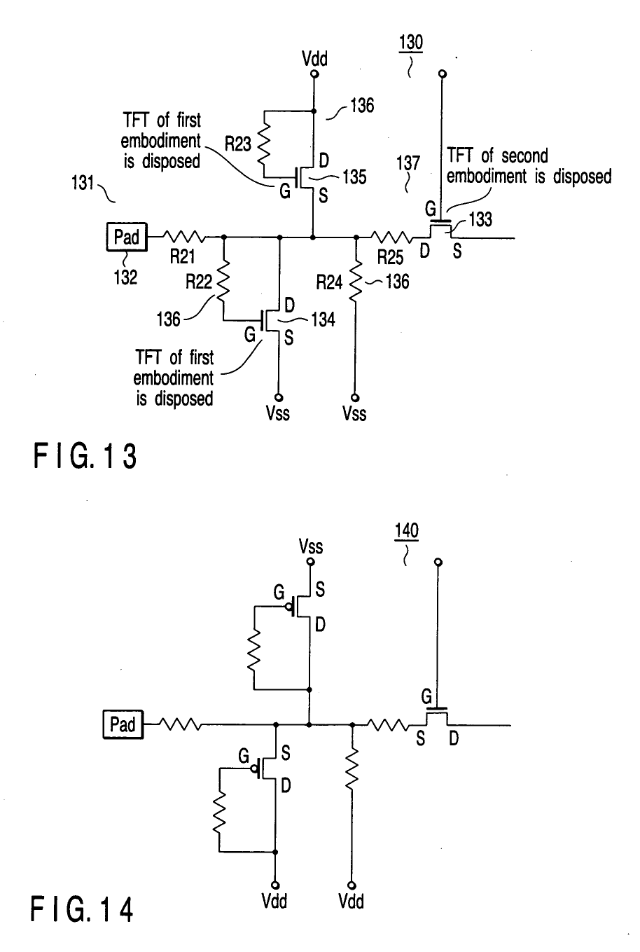

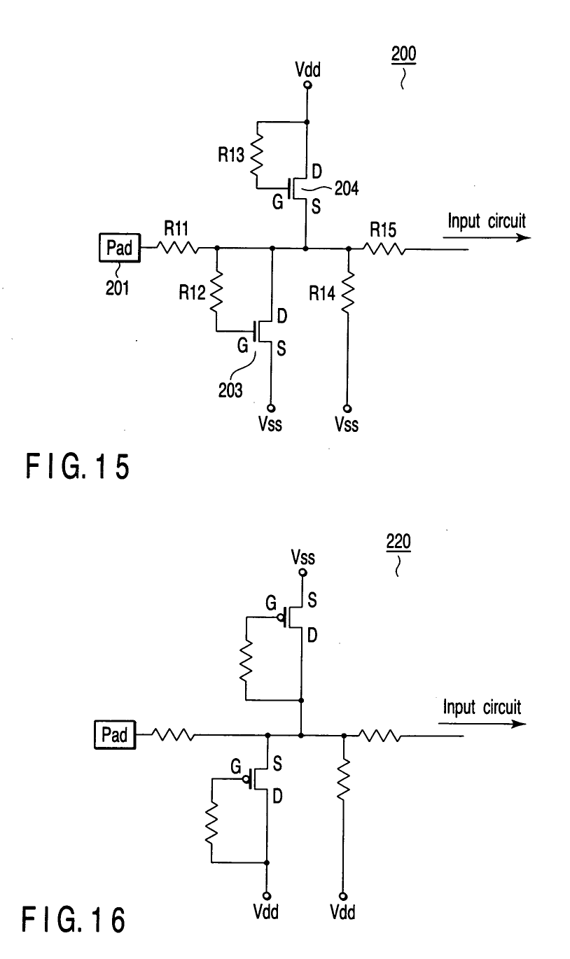

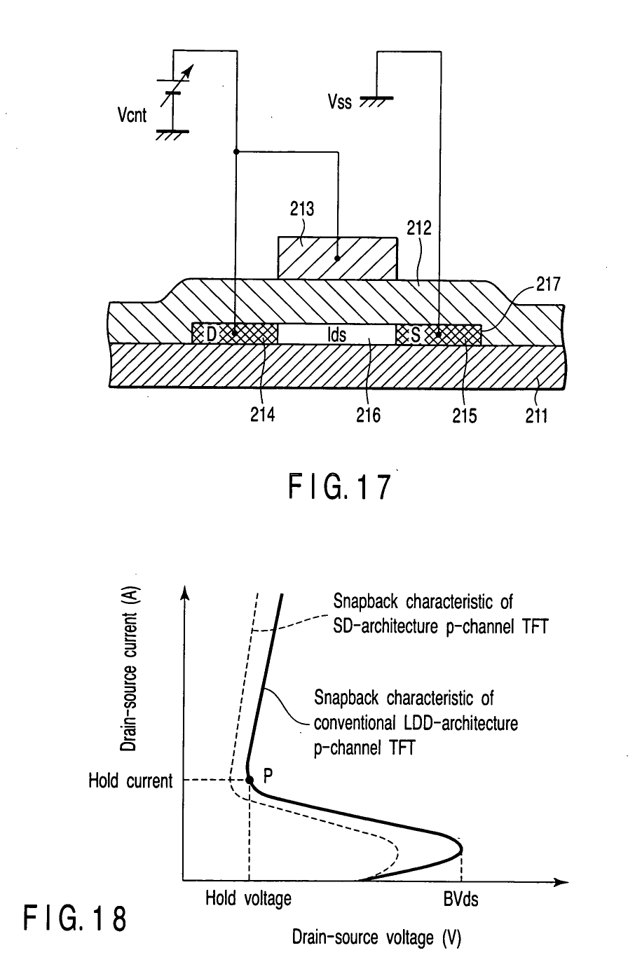

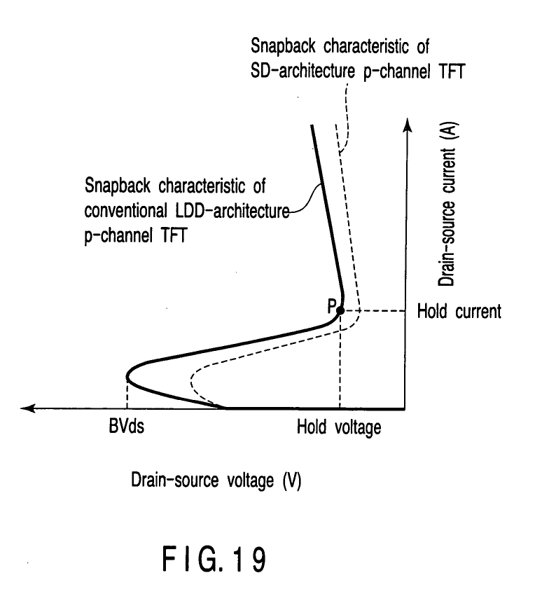

FIG. 7 is a plan view of a TFT 90 according to a second embodiment of the invention, which is usable, for example, as an input/output transistor 133 of an input/output circuit 137 (see FIG. 13) of a liquid crystal display device. FIG. 8 is a cross-sectional view of the TFT 90.

The TFT 90, which is disclosed by way of example in the second embodiment shown in FIG. 7 and FIG. 8, is normally formed in another region of the Si thin film that is formed on the same insulating substrate 72 at the same time as the TFT 70 according to the first embodiment. The TFT 90 can be formed as a p-channel TFT or an n-channel TFT by properly selecting the kind and concentration of impurities, which are to be doped in the respective regions by, e.g. ion implantation, in accordance with the need in connection with the circuit configuration.

The Si thin film 71 of the TFT 90, which is formed as an input/output protection transistor as shown in FIG. 7 by way of example, includes a source region 92, a channel region 93 and a drain region 94. In this example, the Si thin film 71 is formed as a rectangular Si island 83 such that the peripheral part of each TFT is etched away for isolation of the TFTs. Over the Si thin film 71, there are provided a gate insulation film 96 of, e.g. SiO₂, a gate electrode 97, a source electrode 98, a drain electrode 99 and an interlayer insulation film 100. An undercoat insulation film 81 of, e.g. SiO₂ may be provided, where necessary.

In the structure of the TFT 90, the crystal-growth start region 19 is configured to overlap the source region 92 and channel region 93. Specifically, a drain-side end portion and most of a central portion of the channel region 93 are formed in the transverse crystal-growth region 20 that are substantially formed of single crystals. The source-side end portion 101, for example, a left-side part of about 20% of the channel region 93 in FIG. 7, is formed in the crystal-growth start region 19. The drain region 94 is formed in the central transverse crystal-growth region 20, crystal collision region 21 and a right-side transverse crystal-growth region 20′.

FIG. 9A shows a cross-sectional structure of a TFT 110 according to a third embodiment of the invention, and FIG. 9B is a plan view of a semiconductor island of the TFT 110. The TFT 110 includes a drain region 112, a channel region 113 and a source region 114. Over these regions, there are provided a gate insulation film 115 of, e.g. SiO₂, a drain electrode 116, a gate electrode 117, a source electrode 118, and an interlayer insulation film 119. An undercoat insulation film 121 of, e.g. SiO₂ may be provided on the insulating substrate 120, where necessary.

In the structure of the TFT 90, the crystal-growth start region 19, which includes many fine crystals and has many crystal defects, is configured to overlap the drain region 112 and channel region 113. Specifically, the channel region 113 is formed in the drain-side crystal-growth start region 19 and central transverse crystal-growth region 20 that is substantially formed of single crystals. The source region 114 is formed in the transverse crystal-growth region 20.

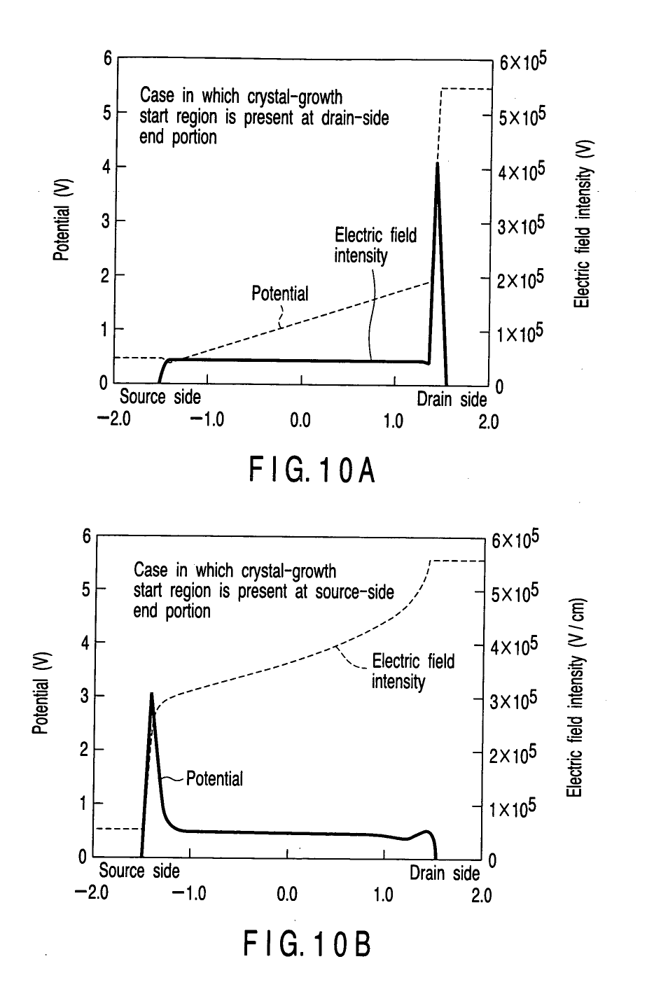

FIG. 10A shows a simulation result of a potential distribution and an electric field distribution in a channel region in a TFT in which a crystal-growth start region with many crystal defects is formed in a drain-side end portion of the channel region, in the case where a gate electrode and a source electrode are short-circuited and a voltage is applied to a drain electrode.

An ATLAS device simulator (manufactured by Silvaco), for instance, is usable for the simulation. In the simulation, the mobility in the channel region was 600 cm²/v·s, which is equal to that of single-crystal Si, and the mobility in the crystal-defect region (polycrystalline region) was 1 cm²/v·s, which is equal to that of amorphous silicon (a-Si). The sheet resistance of the n⁺ layer was calculated under the condition that the impurity concentration was 5×20²⁰ cm⁻³ and the activation ratio was 50%. The gate electrode was made of MoW (midgap material) and the impurity concentration in the channel region of the TFT was set at 2×10¹⁵ cm⁻³. The Si/SiO2 interface trap density was 3.0×10¹¹ cm⁻², the fixed charge was 3.0×10¹¹ cm⁻², and the density of defects in the bulk Si was 3.0×10¹¹ cm⁻². The applied voltages were Vg=0V, Vd=5V, and Vs=Gnd.

In FIG. 10A, the source is formed on the left side and the drain is formed in the right side. A region with many crystal defects is present at a drain-side end portion of the channel region. Thus, this region (right part in FIG. 10A) has a very high resistance, and an electric field concentrates at this region and a potential sharply rises. In this case, the electric field intensity is 4×10⁵V/cm³.

FIG. 10B shows a simulation result of a potential distribution and an electric field distribution in a channel region in a TFT in which a crystal-growth start region with many crystal defects is formed in a source-side end portion of the channel region, in the case where a gate electrode and a drain electrode are short-circuited and a voltage is applied to a source electrode. The conditions for the simulation were the same as in FIG. 10A. In FIG. 10B, the source is formed on the left side and the drain is formed in the right side. In this case, the degree of concentration of electric field at the source-side end portion of the channel region is less than in the drain region in FIG. 10A, and the electric field intensity is 3×10⁵V/cm³.

If the source-drain breakdown voltage of the TFT, which includes the crystal-growth start region with many crystal defects at the drain-side end portion of the channel region, is actually measured by applying the same voltage as in the above-described simulation, it is found that the breakdown voltage is relatively low. A possible reason is that if crystal defects are present on the drain side, an electric field concentrates at the drain-side end portion. On the other hand, in the case of the TFT with crystal defects on the source side, an actual measurement result that was obtained shows that the source-drain breakdown voltage is higher than in the case where crystal defects are present on the drain side. A possible reason is that the degree of concentration of electric field is less than in the case where crystal defects are present on the drain side.

FIG. 11 shows a simulation result of the relationship between a source-drain voltage and a drain current, which was obtained by similarly using the ATLAS device simulator. In FIG. 11, the characteristics of the TFT (indicated by a solid line), which has the region with many crystal defects at the source-side end portion of the channel region, are compared with those of the TFT (indicated by a broken line), which has the region with many crystal defects at the drain-side end portion of the channel region. In the case (broken line) where the drain-side end portion of the channel region is polycrystalline with many crystal defects, the drain current sharply increases when the source-drain voltage is about 2V, and the source-drain breakdown voltage is about 2V. On the other hand, in the case (solid line) where the source-side end portion of the channel region is polycrystalline, the drain current gradually increases and does not sharply increase in the range in which the source-drain voltage is within 5V. Thus, in this case, a higher breakdown voltage is obtained.

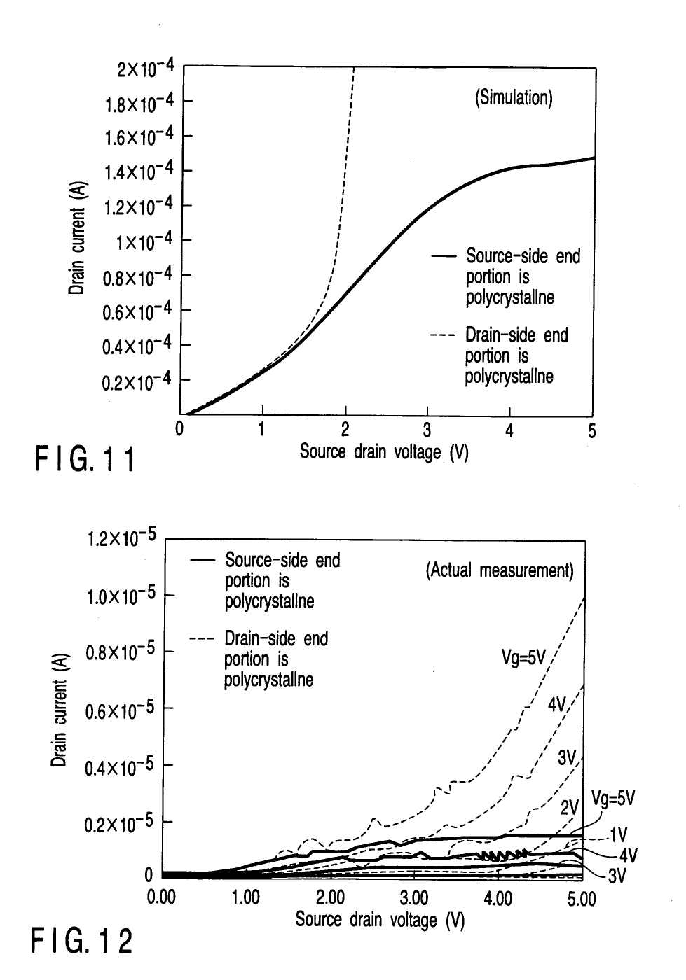

FIG. 12 shows an actual measurement result of the relationship between the source-drain voltage and the drain current in the case (solid line) where the source-side end portion of the channel region is polycrystalline and in the case (broken line) where the drain-side end portion of the channel region is polycrystalline. In the measurement, the gate voltage Vg is changed from 1V to 5V in units of 1V. FIG. 12 shows that the drain current increases more sharply in the case where the drain-side end portion of the channel region is polycrystalline, and a higher effect of absorption of surge voltage is obtained.

As has been described above, there is asymmetry in source-drain breakdown voltage (BVds) between the TFT in which the drain-side end portion of the channel region has many crystal defects and the TFT in which the source-side end portion of the channel region has many crystal defects. The source-drain breakdown voltage (BVds) is lower in the case where the drain-side end portion of the channel region has many crystal defects than in the case where the source-side end portion of the channel region has many crystal defects. The TFT with the lower breakdown voltage can effectively be used as the input/output protection transistor. The above description is directed to the n-type TFT, but the same applies to the p-type TFT.

FIG. 13 shows a fourth embodiment of the present invention. In this embodiment, n-type TFTs are disposed in an input/output protection circuit 130 of the liquid crystal display device as the TFTs according to the present invention. A pad 132 is an input/output pad that constitutes an input/output terminal section 131. An input signal from an external circuit (not shown) is delivered to the pad 132. When the input signal is delivered, electrostatic noise is also input to the pad 132 in usual cases. Reference numerals R21 to R25 indicate resistors that are represented as equivalent circuit components of parasitic resistances of wiring conductors in the input/output protection circuit 130. When the wiring conductors are designed, the parasitic resistances thereof are set, for example, such that the value of the resistor R21 is 100Ω, the value of the resistor R22 is 100Ω, the value of the resistor R23 is 100Ω, the value of the resistor R24 is 50 to 100Ω, and the value of the resistor R25 is 500Ω.

The resistors R22 and R23 represent the parasitic resistances of the wires that short-circuit the gates of input/output protection transistors 134 and 135, which constitute a protection circuit section 136, and the drains of the input/output protection transistors 134 and 135. The source of the input/output protection transistor 134 is connected to a power supply Vss (e.g. 0 to −5V). A current flows in the transistor 134 when electrostatic noise with positive charge is input. On the other hand, the input/output protection transistor 135 is connected to a power supply Vdd (e.g. 5 to 10V). A current flows in the transistor 135 when electrostatic noise with negative charge is input. The resistor R24 of the protection circuit section 136 is set to have a lower resistance value than the resistor R25 that constitutes the input/output circuit section 137. The resistor R24 represents the parasitic resistance of the wire for causing a surge current, which has not completely flowed through the input/output protection transistors 134 and 135, to flow, and the resistor R24 is connected to the power supply Vss.

The transistor of the second embodiment of the invention, which has a high source-drain breakdown voltage, is disposed as the input/output transistor 133 of the input/output circuit section 137. The transistor of the first embodiment of the invention, which has a low source-drain breakdown voltage, is disposed as each of the input/output protection transistors 134 and 135 of the protection circuit section 136. Thereby, for example, when electrostatic noise is input to the pad 132, the input/output protection transistors 134 and 135 are turned on earlier than the input/output transistor 133. Thus, the input/output transistor 133 can be protected.

As the input/output transistor 133, a TFT with a channel region that includes no polycrystalline portion may be substituted for the transistor of the second embodiment in which the source-side end portion of the channel region is the polycrystalline portion. In addition, the input/output protection circuit may be formed using p-type TFTs as the input/output protection transistors.

The protection circuit section 136 is formed using the TFT that includes the polycrystalline Si or amorphous Si region with many crystal defects at the drain-side end portion of the channel region. On the other hand, the input/output circuit section 137 is formed using the TFT that includes the substantially single-crystal region with good crystallinity in the channel region. With this structure, the protection circuit of the input section of the electronic device can be formed without increasing the number of masks, compared to the prior-art fabrication process of using only the conventional TFT structure including a plurality of TFTs with different breakdown voltages BVsd.

By virtue of the formation of the polycrystalline Si or amorphous Si region with many crystal defects at the drain-side end portion of the channel region, even if a large electrostatic surge current is applied to the input section of the electronic device, the surge current can be alleviated by the crystal-defect region. Therefore, destruction of the TFT can be prevented.

FIG. 13 shows the embodiment in which the n-channel thin-film transistors are used. A similar protection circuit can be formed using p-channel thin-film transistors, as shown in FIG. 14.

The TFTs according to the above-described protection circuit can easily be fabricated using recrystallized semiconductor thin films that are obtained by the above-described phase modulation crystallizing method.

An input/output protection circuit according to the present invention is used for an electronic device, and comprises at least a plurality of thin-film transistors. The input/output protection circuit includes an input/output terminal section that receives an input signal, an input/output circuit section that delivers the input signal to the electronic device, and a protection circuit section that is provided between the input/output terminal section and the input/output circuit section. The protection circuit section is formed using at least a thin-film transistor wherein a central portion and a source-side end portion of a channel region are provided in a substantially single-crystal semiconductor thin film, and a drain-side end portion of the channel region is provided in a polycrystalline or amorphous semiconductor thin film.

As the thin-film transistor, a transistor in which a drain-side end portion of a channel region is formed of a growth start region can be used.

In addition, an input/output protection circuit according to the present invention is used for an electronic device, and comprises at least a plurality of thin-film transistors. The input/output protection circuit includes an input/output terminal section that receives an input signal, an input/output circuit section that delivers the input signal to the electronic device, and a protection circuit section that is provided between the input/output terminal section and the input/output circuit section. The input/output circuit section is formed using at least a thin-film transistor wherein a central portion and a drain-side end portion of a channel region are provided in a substantially single-crystal semiconductor thin film, and a source-side end portion of the channel region is provided in a polycrystalline or amorphous semiconductor thin film.

As the thin-film transistor, a transistor in which a source-side end portion of a channel region is formed of a growth start region can be used.

Moreover, an input/output protection circuit according to the present invention is used for an electronic device, and comprises at least a plurality of thin-film transistors. The input/output protection circuit includes an input/output terminal section that receives an input signal, an input/output circuit section that delivers the input signal to the electronic device, and a protection circuit section that is provided between the input/output terminal section and the input/output circuit section. The protection circuit section is formed using at least a thin-film transistor wherein a central portion and a source-side end portion of a channel region are provided in a substantially single-crystal semiconductor thin film, and a drain-side end portion of the channel region is provided in a polycrystalline or amorphous semiconductor thin film, and the input/output circuit section is formed using at least a thin-film transistor wherein a central portion and a drain-side end portion of a channel region are provided in a substantially single-crystal semiconductor thin film, and a source-side end portion of the channel region is provided in a polycrystalline or amorphous semiconductor thin film.

Besides, another input/output protection circuit according to the present invention is used for an electronic device, and comprises at least a plurality of thin-film transistors. The input/output protection circuit includes an input/output terminal section that receives an input signal, an input/output circuit section that delivers the input signal to the electronic device, and a protection circuit section that is provided between the input/output terminal section and the input/output circuit section. The protection circuit section is formed using at least a transistor in which a drain-side end portion of a channel region is formed of a growth start region, and the input/output circuit section is formed using at least a transistor in which a source-side end portion of a channel region is formed of a growth start region.

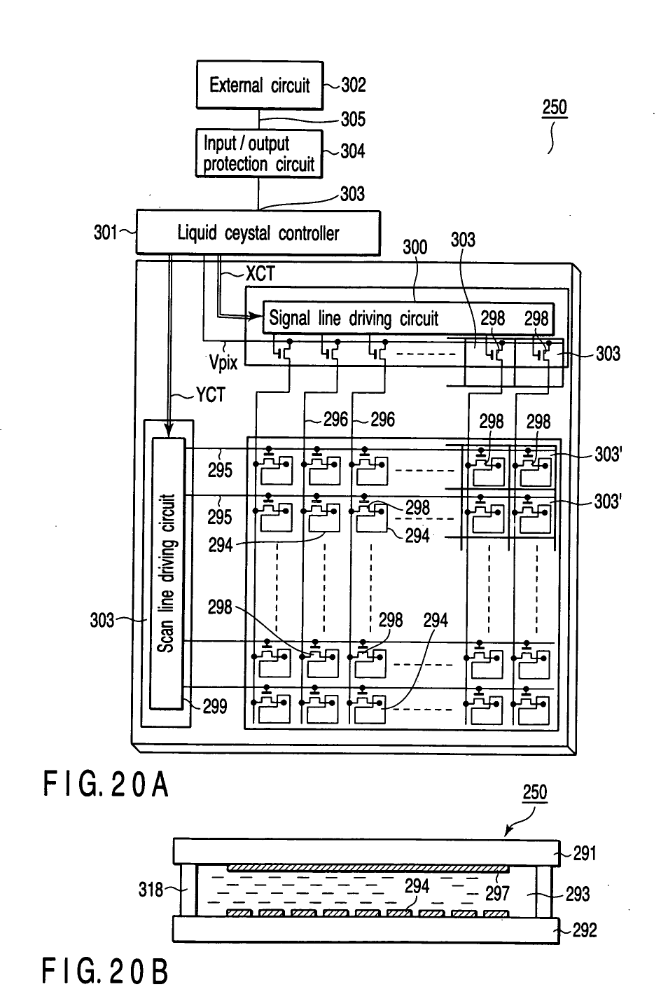

FIG. 20A and FIG. 20B show a specific example of a liquid crystal display device 250 that uses the input/output protection circuit 130, 140 according to the present invention, as shown in FIG. 13 or FIG. 14. Reference numerals 303 and 303′ designate formation regions where thin-film transistors and pixels, which constitute the liquid crystal display device 250, are formed. As is shown in FIG. 20B, the liquid crystal display device 250 includes a-pair of upper and lower transparent substrates 291 and 292, a liquid crystal layer 293, a plurality of pixel electrodes 294 and a counter-electrode 297.

The paired transparent substrates 291 and 292 may be formed of, e.g. glass substrates. The transparent substrates 291 and 292 are bonded to each other via a frame-shaped seal material 318. The liquid crystal layer 293 is sealed in the region that is surrounded by the paired transparent substrates 291 and 292 and the seal material 318.

On the inner surface of one of the paired transparent substrates 291 and 292, for example, on the inner surface of the lower substrate 292, there are provided a plurality of pixel electrodes 294 arranged in a matrix in row and column directions, a plurality of thin-film transistors 298 connected to the associated pixel electrodes 294, and a plurality of scan lines 295 and signal lines 296 that are electrically connected to the thin-film transistors 298. In this embodiment, the thin-film transistors 298 and pixel electrodes 294 are formed on the device formation regions 303 and 303′.

The scan lines 295 extend in the row direction and are connected to the gates of the thin-film transistors 298. The scan lines 295 are connected at one end to a scan line driving circuit 299. The signal lines 296 extend in the column direction and are connected to the thin-film transistors 298. The signal lines 296 are connected at one end to a signal line driving circuit 300. The scan line driving circuit 299 and signal line driving circuit 300 are connected to a liquid crystal controller 301. The liquid crystal controller 301 receives image signals and sync signals from an external circuit 302, and generates a pixel video signal Vpix, a vertical scan control signal YCT and a horizontal scan control signal XCT. An input section 303 of the liquid crystal controller 301 is connected to the external circuit 302 via an input/output protection circuit 304 according to the present invention, as shown in FIG. 13 or FIG. 14 by way of example. The input/output protection circuit 304 prevents an undesirable high voltage, which comes from the external circuit 302 and a connection line 305 between the external circuit 302 and the input/output protection circuit 304, from being directly applied to the liquid crystal controller 304.

The input/output protection circuit 304, together with the liquid crystal controller 301, can be formed on the substrate 292 as the liquid crystal display device 250 by the same fabrication steps as an integral body with the liquid crystal display device 250. The thin-film transistors 70 and 90 according to the present invention may properly be applied to the internal circuit of the liquid crystal display device 250, for example, to the scan line driving circuit 299 or signal line driving circuit 300. Thereby, the internal circuit part can directly be protected.

The present invention can be practiced in various forms without departing from the spirit or the principal features of the invention. The above-described embodiments are mere examples, and the invention should not restrictively be interpreted. The scope of the invention is defined by the appended claims, and is not restricted by the description in the specification. Modifications and changes, which belong to the equivalent scope of the appended claims, fall within the scope of the present invention.

What is claimed is:

1. A thin-film transistor comprising:
a source region, a channel region and a drain region, which are formed in a semiconductor thin film that includes a substantially single-crystal region and a polycrystalline or amorphous region, and a gate insulation film and a gate electrode, which are formed over the channel region,
wherein a central portion and a source-side end portion of the channel region are provided in the substantially single-crystal semiconductor thin film, and a drain-side end portion of the channel region is provided in the polycrystalline or amorphous semiconductor thin film.

2. A thin-film transistor comprising:
a source region, a channel region and a drain region, which are formed in a semiconductor thin film that includes a substantially single-crystal region and a polycrystalline or amorphous region, and a gate insulation film and a gate electrode, which are formed over the channel region,
wherein a central portion and a drain-side end portion of the channel region are provided in the substantially single-crystal semiconductor thin film, and a source-side end portion of the channel region is provided in the polycrystalline or amorphous semiconductor thin film.

3. The thin-film transistor according to claim 1, wherein the polycrystalline semiconductor thin film or the amorphous semiconductor thin film includes fine crystals with a crystal grain size of 0.2 μm or less.

4. The thin-film transistor according to claim 2, wherein the polycrystalline semiconductor thin film or the amorphous semiconductor thin film includes fine crystals with a crystal grain size of 0.2μ or less.

5. A thin-film transistor comprising:
a source region, a channel region and a drain region, which are formed in a semiconductor thin film, and a gate insulation film and a gate electrode, which are formed over the channel region,
wherein the semiconductor thin film is formed of a recrystallized semiconductor thin film, and the channel region is formed of a growth start region and a crystal-growth region of the recrystallized semiconductor thin film.

6. The thin-film transistor according to claim 5, wherein a drain-side end portion of the channel region is formed of the growth start region.

7. The thin-film transistor according to claim 5, wherein a source-side end portion of the channel region is formed of the growth start region.

8. The thin-film transistor according to claim 5, wherein the growth start region includes fine crystals with a crystal grain size of 0.2μ or less.

9. The thin-film transistor according to claim 6, wherein the growth start region includes fine crystals with a crystal grain size of 0.2μ or less.

10. The thin-film transistor according to claim 7, wherein the growth start region includes fine crystals with a crystal grain size of 0.2μ or less.

11. The thin-film transistor according to claim 1, wherein the semiconductor is Si.

12. The thin-film transistor according to claim 2, wherein the semiconductor is Si.

13. The thin-film transistor according to claim 5, wherein the semiconductor is Si.

14. A liquid crystal display device that employs the thin-film transistor according to any one of claims 1, 2 and 5.
